(19) United States
(12) Patent Application Publication
(10) Pub. No.: US 2022/0260317 A1
(43) Pub. Date: Aug. 18, 2022

(54) COOLING DEVICE

(71) Applicant: HONDA MOTOR CO., LTD., Tokyo (JP)

(72) Inventor: Takeshi MORISHITA, Saitama (JP)

(21) Appl. No.: 17/590,031

(22) Filed: Feb. 1, 2022

(30) Foreign Application Priority Data
Feb. 15, 2021 (JP) 2021-021949

(51) Int. Cl. F28D 7/10

(52) U.S. Cl. CPC F28D 7/10

(57) ABSTRACT

A cooling device includes an inner casing defining an inner bore, an outer casing surrounding the inner casing so as to define a cooling chamber therebetween and having a cooling surface on exterior thereof, the cooling chamber accommodating therein a first cooling medium that changes phases depending on surrounding temperature, and a cooling medium circuit configured to circulate a second cooling medium through the inner bore of the inner casing.

### TECHNICAL FIELD

The present invention relates to a cooling device, and more particularly to a cooling device suitable for cooling an electronic device such as PCUs and CPUs.

### BACKGROUND ART

The heat pipe is known in the art as an efficient device for cooling objects such as semiconductor devices. A cooling medium which is in liquid form and contained in a pipe is brought into thermal contact with an object to be cooled at one end thereof, and the heated cooling medium is vaporized. The vaporized cooling medium flows along the heat pipe and condenses back into liquid form at the other end of the heat pipe. The condensed cooling medium returns to the first end of the heat pipe through gravity or capillary action to repeat this cycle. US20190/339022A1 discloses a vapor chamber device having such a heat pipe encased in a flat rectangular casing. The second end of the heat pipe is provided with cooling fins.

In electric vehicles and other applications, there is an ever growing need for efficient and compact cooling devices.

### SUMMARY OF THE INVENTION

In view of such a need, a primary object of the present invention is to provide a compact and efficient cooling device.

To achieve such an object, the present invention provides a cooling device, comprising: an inner casing (20) defining an inner bore (28); an outer casing (22) surrounding the inner casing so as to define a cooling chamber (14) therebetween and having a cooling surface (16A) on exterior thereof, the cooling chamber accommodating therein a first cooling medium (L) that changes phases depending on surrounding temperature; and a cooling medium circuit (42) configured to circulate a second cooling medium through the inner bore of the inner casing.

The first cooling medium is required to travel a short distance between the inner surfaces of the inner casing and the outer casing so that an efficient heat transfer can be accomplished. Since this movement of the first cooling medium takes place across a large area, the efficiency in heat transfer can be further improved.

Preferably, the inner casing comprises a first pipe having a laterally elongated cross section and, and the outer casing comprises a second pipe having the first pipe nested therein, and having a similar cross sectional shape as the first pipe.

Thereby, the cooling device can be formed as a highly compact structure which is easy to manufacture.

Preferably, the first pipe and the second pipe have a substantially same axial length, and the cooling device further comprises a pair of lid members (24, 26) that close the cooling chamber at axial ends of the first pipe and the second pipe. Thereby, the manufacturing process for the cooling device can be simplified.

Preferably, a pair of lid members are provided with an inlet opening (30) and an outlet opening (34), respectively, and the cooling medium circuit is connected to the inlet opening and the outlet opening so as to circulate the second cooling medium from the inlet opening to the outlet opening. Thereby, the manufacturing process can be simplified even further.

Preferably, the first pipe has a laterally elongated rectangular cross section, and the second pipe has a similar cross sectional shape as the first pipe, and the cooling surface is provided on an outer surface of a long side of the first pipe. Thereby, the cooling device can provide a large cooling surface, and can be conveniently fitted on semiconductor devices and other objects that are desired to be cooled.

Preferably, the first pipe and the second pipe each consist of an extruded member. Thereby, the manufacturing process can be particularly simplified.

Preferably, the inner casing has a substantially smaller wall thickness than the outer casing. Thereby, the heat transfer between the first cooling medium and the second cooling medium can be maximized owing to the small wall thickness of the inner casing. Even when the pressure of the second cooling medium is high, the surrounding outer casing and the first cooling medium reinforces the inner casing against the pressure from the second cooling medium.

Preferably, the inner casing and the outer casing are lined with porous material (27) on surfaces thereof facing the cooling chamber.

The porous material serves as a wick which maximizes heat transfer between the first cooling medium and the inner and outer casings.

The present invention thus provides a compact and efficient cooling device.

### BRIEF DESCRIPTION

### Brief Description of the Drawings

Now the present invention is described in the following with reference to the appended drawings, in which:

FIG. 1 is a longitudinal sectional view of a cooling device according to the present invention; and

FIG. 2 is a cross sectional view taken along II-II of FIG. 1.

### DETAILED DESCRIPTION OF THE PREFERRED EMBODIMENT(S)

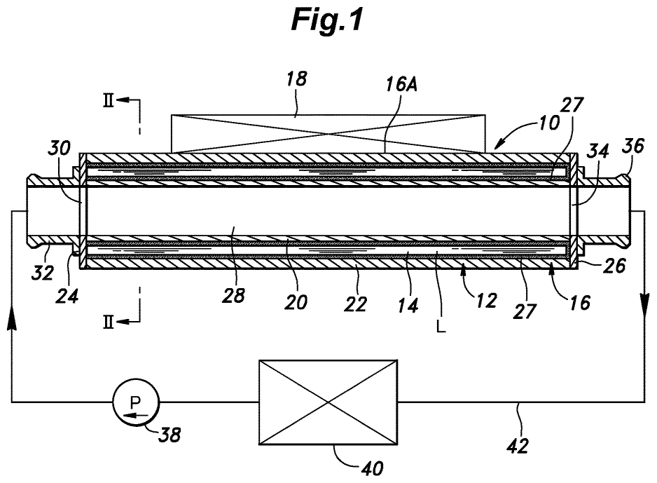

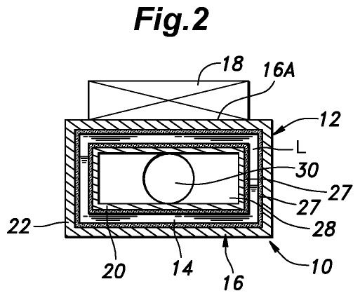

FIGS. 1 and 2 show a cooling device 10 according to the present invention. The cooling device 10 essentially consists of a vapor chamber device 12 that makes use of a phase change of a cooling medium.

The vapor chamber device 12 includes a casing 16 which is formed by a rectangular inner tube 20 having a laterally elongated rectangular cross section and a certain axial length, a rectangular outer tube 22 having a laterally elongated rectangular cross section similar to that of the inner tube 20 and the same axial length as the inner tube 20. The inner tube 20 is nested in the outer tube 22 such that a substantially same gap is defined on all sides. A pair of lid members 24 and 26 are attached to either axial end of the assembly consisting of the inner tube 20 and the outer tube 22 so that an enclosed annular chamber 14 having an annular cross sectional shape and elongated in the axial direction is defined thereby. In the illustrated embodiment, the lid members 24 and 26 are welded or brazed to the axial ends of the inner tube 20 and the outer tube 22.

The annular chamber 14 is filled with a cooling medium L (first cooling medium) consisting of a material that changes phases at a certain temperature. For instance, the cooling medium is in liquid form at a low temperature, and turns into a gaseous form at a high temperature. When turning from the liquid form to the gaseous form, the cooling medium absorbs a substantial amount of heat (latent heat). Alternatively, the cooling medium is in solid form at a low temperature, and turns into a liquid form at a high temperature. When turning from the solid form to the liquid form, the cooling medium absorbs a substantial amount of heat (latent heat).

The inner tube 20 and the outer tube 22 may be made of extruded material. The inner tube 20 and the outer tube 22 are preferably made of thermally conductive material such as copper, copper alloy, aluminum, aluminum alloy, or other thermally conductive material.

In the illustrated embodiment, the inner tube 20 has a smaller wall thickness than the outer tube 22. For instance, the wall thickness of the inner tube 20 is 2 mm, and the wall thickness of the outer tube 22 is substantially less than 2 mm.

The inner tube 20 and the outer tube 22 are lined with a layer of porous material which is referred to as wick 27 on the surfaces thereof facing the annular chamber 14. The wick 27 may consist of sintered metal, plastic, natural fiber or any other porous material. When assembling this vapor chamber device 12, the inner tube 20 and the outer tube 22, and one of the lid members 26 are joined to one another, and the inner surfaces of these members are lined with the wick 27. Thereafter, the other lid member 24 is attached to the open end of the inner tube 20 and the outer tube 22. It is also possible to line the inner tube 20 and the outer tube 22, and the lid members 26 with the wick 27 before assembling these members together.

One of the lid members 24 is formed with an inlet opening 30 communicating with an inner bore 28 of the inner tube 20. A nipple 32 communicating with the inlet opening 30 is attached to the outer side of the lid member 24 for the convenience of connecting tubing thereto. The other lid member 26 is formed with an outlet opening 34 communicating with the other end of the inner bore 28 of the inner tube 20. A nipple 36 communicating with the outlet opening 34 is attached to the outside of the lid member 26. The inner diameters of the nipples 32 and 36 and the openings 30 and 34 are equal to the inner diameter of the inner bore 28 of the inner tube 20 so that an inner bore 28 having a constant cross section is formed from one end of the vapor chamber device 12 to the other.

The inner bore 28 is connected to a circulation passage 42 which is provided with a pump 38 and a radiator 40. The circulation passage 42 circulates a cooling medium (second cooling medium) consisting of water or a water-based coolant. The cooling medium expelled from the pump 38 is forwarded to the inlet opening 30, and after passing through the inner bore 28, is expelled from the outlet opening 34. The cooling medium expelled from the outlet opening 34 is forwarded to the radiator 40, and is expelled from the radiator 40 to be drawn by the pump 38. The radiator 40 in this case is configured to exchange heat between the cooling medium and ambient air.

One of the broad sides of the outer tube 22 is provided with a flat outer surface 16A (cooling surface) on which an electronic device 18 which is desired to be cooled is placed. The electronic device 18 may be placed directly on the outer surface 16A of the outer tube 22 or a heat conductive grease or the like may be interposed between the flat outer surface and the electronic device 18.

According to the above configuration, since the entire surface of the inner bore 28 of the inner tube 20 is directly cooled by the second cooling medium flowing therethrough, the first cooling medium in the annular chamber 14 can be favorably cooled. This also contributes to a compact design of the vapor chamber device 12.

The heat exchange between the first cooling medium and the second cooling medium can be enhanced by minimizing the wall thickness of the inner tube 20. Since the inner tube 20 is surrounded by the outer tube 22 via the first cooling medium L, the inner tube 20 is favorably reinforced against the pressure applied by the second cooling medium.

Being made of extruded material, the inner tube 20 and the outer tube 22 are free from material flaws as opposed to stamp formed or otherwise bent material which may involve stress concentration in bends or the likes so that the vapor chamber device 12 can be made highly durable in use.

Since the vapor chamber device 12 can be made as a highly flat, low-profile device, space requirements can be minimized so that the vapor chamber device 12 can be used in highly tight spaces. Further, owing to the double-walled structure, the vapor chamber device 12 can withstand high loads in spite of the low-profiled configuration thereof.

Although the present invention has been described in terms of a preferred embodiment thereof, it is obvious to a person skilled in the art that various alterations and modifications are possible without departing from the scope of the present invention which is set forth in the appended claims.

1. A cooling device, comprising:
an inner casing defining an inner bore;
an outer casing surrounding the inner casing so as to define a cooling chamber therebetween and having a cooling surface on exterior thereof, the cooling chamber accommodating therein a first cooling medium that changes phases depending on surrounding temperature; and
a cooling medium circuit configured to circulate a second cooling medium through the inner bore of the inner casing.

2. The cooling device according to claim 1, wherein the inner casing comprises a first pipe having a laterally elongated cross section and, and the outer casing comprises a second pipe having the first pipe nested therein, and having a similar cross sectional shape as the first pipe.

3. The cooling device according to claim 2, wherein the first pipe and the second pipe have a substantially same axial length, and the cooling device further comprises a pair of lid members that close the cooling chamber at axial ends of the first pipe and the second pipe.

4. The cooling device according to claim 3, wherein the lid members are provided with an inlet opening and an outlet opening, respectively, and the cooling medium circuit is connected to the inlet opening and the outlet opening so as to circulate the second cooling medium from the inlet opening to the outlet opening.

5. The cooling device according to claim 4, wherein the first pipe has a laterally elongated rectangular cross section, and the second pipe has a similar cross sectional shape as the first pipe, and the cooling surface is provided on an outer surface of a long side of the first pipe.

6. The cooling device according to claim 2, wherein the first pipe and the second pipe each consist of an extruded member.

7. The cooling device according to claim 1, wherein the inner casing has a substantially smaller wall thickness than the outer casing.

8. The cooling device according to claim 1, wherein the inner casing and the outer casing are lined with porous material on surfaces thereof facing the cooling chamber.
